(19) United States
(12) Patent Application Publication
(10) Pub. No.: US 2012/0148865 A1
(43) Pub. Date: Jun. 14, 2012

(54) ARTICLE AND METHOD FOR MANUFACTURING ARTICLE

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); SHYAN-JUH LIU, Tu-Cheng (TW); CONG LI, Shenzhen (CN)

(73) Assignees: HON HAI PRECISION INDUSTRY CO., LTD., Tu-Cheng (TW); HONG FU JIN PRECISION INDUSTRY (ShenZhen) CO., LTD ., Shenzhen City (CN)

(21) Appl. No.: 13/082,541

(22) Filed: Apr. 8, 2011

(30) Foreign Application Priority Data
Dec. 9, 2010 (CN) 201010580447.2

(51) Int. Cl. B32B 15/04; C23C 14/34

(52) U.S. Cl. 428/627; 204/192.15

(57) ABSTRACT

An article includes a niobium alloy substrate; an iridium layer deposited on the niobium alloy substrate; and a chromium oxygen-nitride layer deposited on the iridium layer opposite to the iridium layer.

### Background

1. Technical Field

The exemplary disclosure generally relates to articles and methods for manufacturing the articles.

2. Description of Related Art

Niobium alloy has a high melting point, low density and good castability, so it is widely used in many fields, such as the aerospace industry, and automatic industry. However, Niobium alloy has a low temperature oxidation resistance.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary article and method for manufacturing the article. Moreover, in the drawings like reference numerals designate corresponding parts throughout the several views. Wherever possible, the same reference numbers are used throughout the drawings to refer to the same or like elements of an embodiment.

FIG. 1 is a cross-section of an exemplary embodiment of an article.

FIG. 2 is a schematic view of a magnetron sputtering coating machine for manufacturing the article in FIG. 1.

### DETAILED DESCRIPTION

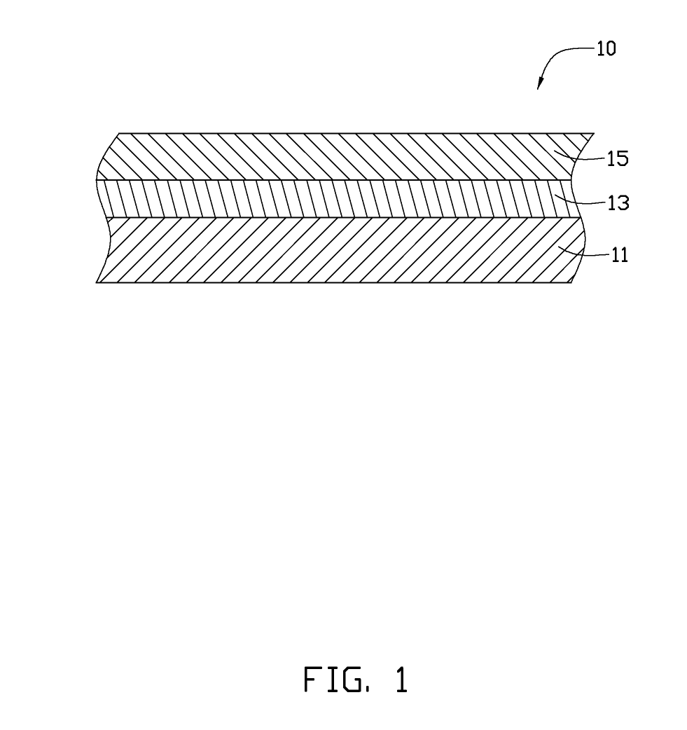

Referring to FIG. 1, an exemplary embodiment of an article 10 includes a niobium alloy substrate 11, a barrier layer made of an iridium layer 13 deposited on the niobium alloy substrate 11, and an oxidation resistance layer made of chromium oxygen-nitride layer 15 deposited on the iridium layer 13 opposite to the niobium alloy substrate 11. The niobium alloy substrate 11 is made of niobium alloy. The iridium layer 13 has a thickness between 2 micrometers and 3.5 micrometers. The chromium oxygen-nitride layer 15 has a thickness between 2 micrometers and 3.5 micrometers. The iridium layer 13 and the chromium oxygen-nitride layer 15 may both be deposited by magnetron sputtering process.

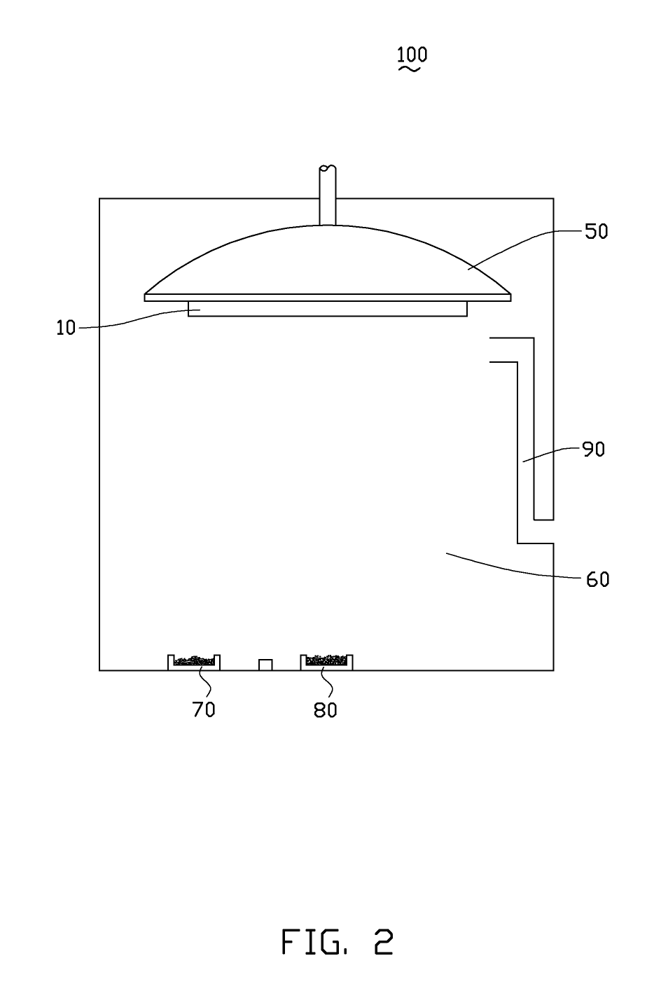

Referring to FIG. 2, a method for manufacturing the article 10 may include at least the following steps.

Providing a niobium alloy substrate 11. The niobium alloy substrate 11 may be made of niobium alloy.

Pretreating the niobium alloy substrate 11, by polishing the niobium alloy substrate 11. The niobium alloy substrate 11 is then washed with a solution (e.g., Alcohol or Acetone) in an ultrasonic cleaner, to remove impurities, such as grease or dirt. The niobium alloy substrate 11 is dried. The niobium alloy substrate 11 is cleaned by argon plasma cleaning. The niobium alloy substrate 11 is retained on a rotating bracket 50 in a vacuum chamber 60 of a magnetron sputtering coating machine 100. The vacuum level inside the vacuum chamber 60 is adjusted to about 8.0×10−3 Pa. Pure argon is fed into the vacuum chamber 60 at a flux between about 400 Standard Cubic Centimeters per Minute (sccm) and about 700 sccm from a gas inlet 90. A bias voltage applied to the niobium alloy substrate 11 is between about −500 volts to about −800 volts for between about 3 minutes and about 10 minutes. The niobium alloy substrate 11 is washed by argon plasma, to further remove grease and dirt. Thus, the binding force between the niobium alloy substrate 11 and the iridium layer 13 is enhanced.

An iridium layer 13 is deposited on the niobium alloy substrate 11. The temperature in the vacuum chamber 60 is adjusted between about 100° C. (Celsius degree) and about 200° C. Argon is fed into the vacuum chamber 60 at a flux between about 20 sccm and 150 sccm from the gas inlet 90. The vacuum level inside the vacuum chamber 60 is set between about 12 Pa and about 18 Pa. An iridium target 70 in the vacuum chamber 60 is evaporated at a power between about 2 kW and about 5 kW. A bias voltage applied to the niobium alloy substrate 11 may be between about −100 volts and about −300 volts, for between about 5 minutes and about 10 minutes, to deposit the iridium layer 13 on the niobium alloy substrate 11. Because iridium has good corrosion-resistance, it can prevent exterior oxygen from diffusing therein at temperature below 1600° C. so the iridium layer 13 can improve the high temperature oxidation resistance of the niobium alloy substrate 11.

A chromium oxygen-nitride layer 15 is deposited on the iridium layer 13. The temperature in the vacuum chamber 60 is set between about 100° C. and about 200° C. Argon is fed into the vacuum chamber 60 at a flux between about 20 sccm and 150 sccm from the gas inlet 90. Oxygen is fed into the vacuum chamber 60 at a flux between about 20 sccm and 80 sccm from the gas inlet 90. Nitrogen is fed into the vacuum chamber 60 at a flux between about 10 sccm and 50 sccm from the gas inlet 90. The vacuum level inside the vacuum chamber 60 is set between about 12 Pa and about 18 Pa. A chromium target 80 in the vacuum chamber 60 is evaporated at a power between about 2 kW and about 5 kW. A bias voltage applied to the niobium alloy substrate 11 may be between about −100 volts and about −300 volts, for between about 150 minutes and about 250 minutes, to deposit the chromium oxygen-nitride on the iridium layer 13.

During deposition of the chromium oxygen-nitride layer 15, atomic chromium can respectively react with atomic oxygen and atomic nitrogen to form chromium-oxide crystal and chromium-nitride phase crystal. Chromium-oxide crystal and chromium-nitride crystal can prevent each other from enlarging, thereby improving the compactness of the chromium oxygen-nitride layer 15, which can prevent exterior oxygen from diffusing in the chromium oxygen-nitride layer 15. Thus, the chromium oxygen-nitride layer 15 increases temperature oxidation resistance of article 10. Additionally, the chromium oxygen-nitride layer 15 has a high melting point, which can prevent the atomic iridium inside the iridium layer 13 from oxidation at temperature above 1600° C.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An article, comprising:
a niobium alloy substrate;
an barrier layer made of an iridium layer, the barrier layer deposited on the niobium alloy substrate; and
an oxidation resistance layer made of a chromium oxygen-nitride layer, the oxidation resistance layer deposited on the iridium layer opposite to the niobium alloy substrate.

2. The article as claimed in claim 1, wherein the iridium layer has a thickness between 2 micrometers and 3.5 micrometers.

3. The article as claimed in claim 1, wherein the chromium oxygen-nitride layer has a thickness between 2 micrometers and 3.5 micrometers.

4. The article as claimed in claim 1, wherein the iridium layer and the chromium oxygen-nitride layer are both deposited by magnetron sputtering process.

5. A method for manufacturing an article comprising steps of:
providing a niobium alloy substrate made of niobium alloy;
depositing a iridium layer on the niobium alloy substrate by magnetron sputtering; and
depositing a chromium oxygen-nitride layer on the iridium layer by magnetron sputtering.

6. The method of claim 5, wherein during depositing the iridium layer on the niobium alloy substrate, the niobium alloy substrate is retained in a vacuum chamber of a magnetron sputtering coating machine; the temperature in the vacuum chamber is adjusted between about 100° C. and about 200 V; argon is fed into the vacuum chamber at a flux between about 20 sccm and 150 sccm; the vacuum level inside the vacuum chamber is set between about 12 Pa and about 18 Pa; an iridium target in the vacuum chamber is evaporated at a power between about 2 kW and about 5 kW; a bias voltage applied to the niobium alloy substrate is between about −100 volts and about −300 volts, for between about 5 minutes and about 10 minutes, to deposit the iridium layer on the niobium alloy substrate.

7. The method of claim 5, wherein during depositing the chromium oxygen-nitride layer on the iridium layer, the niobium alloy substrate is retained in a vacuum chamber of a magnetron sputtering coating machine; the temperature in the vacuum chamber is set between about 100° C. and about 200° C.; argon is fed into the vacuum chamber at a flux between about 20 sccm and 150 sccm; oxygen is fed into the vacuum chamber at a flux between about 20 sccm and 80 sccm; nitrogen is fed into the vacuum chamber at a flux between about 10 sccm and 50 sccm; the vacuum level inside the vacuum chamber is set between about 12 Pa and about 18 Pa; an chromium target in the vacuum chamber is evaporated at a power between about 2 kW and about 5 kW; a bias voltage applied to the niobium alloy substrate is between about −100 volts and about −300 volts, for between about 150 minutes and about 250 minutes, to deposit the chromium oxygen-nitride on the iridium layer.
